(19) United States
(12) Patent Application Publication
(10) Pub. No.: US 2013/0145612 A1
(43) Pub. Date: Jun. 13, 2013

(54) HEAT SINK FIN STRUCTURE BLOCKING ELECTROMAGNETIC RADIATION

(71) Applicants: Diane S. Busch, Durham, NC (US); Troy W. Glover, Raleigh, NC (US); Michael S. June, Raleigh, NC (US); Pradeep Ramineni, Cary, NC (US)

(72) Inventors: Diane S. Busch, Durham, NC (US); Troy W. Glover, Raleigh, NC (US); Michael S. June, Raleigh, NC (US); Pradeep Ramineni, Cary, NC (US)

(73) Assignee: INTERNATIONAL BUSINESS MACHINES CORPORATION, Armonk, NY (US)

(21) Appl. No.: 13/323,811

(22) Filed: Dec. 12, 2011

(51) Int. Cl. G06F 1/20; H01P 1/22; H05K 7/20

(52) U.S. Cl. 29/601; 361/692; 361/679.54

(57) ABSTRACT

A system to remove heat from a heat-generating electronic component within a computer chassis and to contain electromagnetic radiation from traversing high-throughput vents in a bezel that forms a portion of the chassis containment structure comprises a heat sink having a fin structure with an inlet face, an outlet face and interconnected air channels therethrough, a base to engage the component and to transfer heat from the component to the fin structure, wherein the inlet face of the fin structure is disposed proximate the vents to block electromagnetic radiation from traversing the vents. In one embodiment, a heat pipe or a spreader bar moves heat from a base engaging a component distal from the bezel to the fin structure having an air inlet face proximal to the vents.

### BACKGROUND

1. Field of the Invention

The present invention relates to heat sinks to cool heat-generating electronic components within a computer chassis.

2. Background of the Related Art

Computer systems often rely on heat sinks positioned on heat-generating electronic components, such as processors, to maintain performance of the component by removing heat and maintaining a favorable operating temperature. Heat sinks generally conduct heat generated by the component to fins where the heat is transferred to air flowing across the large surface area of the fins. Heat sinks are available with several types of air-cooled fins including pin fins, straight fins, folded fins, flared fins and extruded fins. With increasing processor power densities, more heat is generated by processors disposed within the limited space of a computer chassis, thereby giving rise to a need for improved heat sink systems.

Most computer chassis, especially those in high density computer environments, are designed to shield nearby electronic components from electromagnetic radiation (EMR) generated by components within the chassis and to isolate the components in the chassis from EMR generated by the nearby electronic components. Left unabated, EMR interferes with the efficient operation of electronic components. Electromagnetic interference (EMI) is generally abated by surrounding EMR-generating components with a grounded metal chassis that operates as a Faraday cage to block EMR from traversing the chassis.

A bezel is a panel that connects to an open end of a chassis to form a portion of the Faraday cage to contain EMR. A bezel may facilitate user access to one or more computer components within the chassis and generally includes a number of small vents to facilitate the flow of air into the chassis to remove heat from heat-generating electronic components disposed therein. Air-cooled heat sinks are used to remove heat from the electronic components and transfer that heat into the air flow. This is accomplished by conducting heat from the component through a heat sink base to a set of fins or a fin structure for dissipation. Air may be drawn through the chassis using an air mover, such as a fan, or air movement through a chassis may be provided by an external air mover disposed to move air through multiple chassis within a server room or a server rack.

Because the bezel forms a portion of a chassis boundary, the vents within a bezel are generally made small enough to abate EMR from traversing the Faraday cage via the vents. Vents that are small relative to the wavelength of the EMR deflect, absorb or scatter a large portion of the EMR and are therefore able to contain EMR generated within the chassis and to isolate components within the chassis from EMR sources outside the chassis. However, small vents generally impede the flow of air through the chassis, thereby resulting in air movers running more frequently or running at higher speeds to compensate for the restricted cooling air flow through the bezel. Larger vents in the bezel may provide improved air flow, but larger vents allow greater amounts of EMR to traverse the bezel. It will be understood that there is a trade-off between providing unimpeded air flow through the chassis and shielding electronic components from EMR. The vents in a conventional bezel must be small relative to the wavelength of the EMR so that the EMR will be blocked by the bezel.

### BRIEF SUMMARY

One embodiment of the present invention provides a system comprising a chassis having an air inlet and an air outlet, a circuit board with a heat-generating electronic component within the chassis, a heat sink having a base to engage the heat-generating electronic component and a fin structure with an inlet face, an outlet face and a plurality of interconnected air channels therebetween, wherein the fin structure spans the air inlet and blocks electromagnetic radiation (EMR) from traversing the air inlet.

Another embodiment of the invention provides a method to contain EMR within a computer chassis comprising , disposing a heat-generating electronic component on a circuit board within a chassis having an air inlet, engaging the heat-generating electronic component with a base of a heat sink, wherein the base is thermally coupled to a fin structure having an inlet face, an outlet face and interconnected air channels therebetween, and positioning the inlet face of the fin structure forward within the chassis and proximal the air inlet to the chassis to block EMR from traversing the air inlet to the chassis.

### BRIEF DESCRIPTION OF THE SEVERAL VIEWS OF THE DRAWINGS

FIG. 1 is a perspective view of a conventional electromagnetic radiation (EMR) containment system comprising a chassis and a bezel with restricted vents to impede EMR from traversing the bezel.

FIG. 2 is a perspective view of an embodiment of an EMR containment system of the present invention having a chassis and a bezel connected to a front of the chassis to position low-impedance vents proximal the inlet face of the fin structure to impede EMR from traversing the bezel.

FIG. 3 is an enlarged perspective view of a portion of the EMR containment system of FIG. 2 with the bezel removed to reveal the position of the inlet face of the fin structure of the heat sink proximate the low-impedance vents of the bezel shown in FIG. 2.

FIG. 4 is a side elevation view of the EMR containment system of FIGS. 2 and 3 illustrating the proximity of the inlet face of the fin structure of the heat sink relative to the low-impedance vents of the bezel.

FIG. 5 is a side elevation view of an alternate embodiment of the EMR containment system of the present invention having a bezel with low-impedance vents disposed proximate the inlet face of a fin structure coupled through a heat bus to a base on a component located distal to the bezel.

### DETAILED DESCRIPTION

One embodiment of the present invention provides an electromagnetic radiation (EMR) containment system comprising a heat sink to cool a heat-generating electronic component within a computer chassis, where the heat sink has a fin structure that cooperates with low-impedance vents within a bezel to provide improved cooling air flow to the heat sink and to block EMR from traversing the chassis. The fin structure comprises an inlet face, an outlet face and a plurality of interconnected air channels therebetween. The inlet face of the fin structure is disposed at a forward position near an air inlet across front of the chassis, and the bezel with low-impedance vents is connected to the front of the chassis to position the vents across the air inlet proximal to the inlet face of the fin structure. The fin structure is thermally coupled to a base in thermal contact or communication with a heat-generating electronic component. The fin structure dissipates heat from the component to air entering the chassis through the bezel vents and flowing through the air channels of the fin structure. The fin structure is disposed generally intermediate the vents of the bezel and EMR-generating components within the chassis and the fin structure to block EMR from traversing the low-impedance vents of the bezel.

In one embodiment of the EMR containment system of the present invention, a fin structure comprises a honeycomb structure; that is, the fin structure comprises an inlet face having a plurality of interconnected hexagonal air channel inlets, an outlet face comprising hexagonal air channel outlets and a plurality of air channels therebetween with hexagonal cross-sections. The inlet face of the fin structure is disposed at a forward position near an air inlet in the front of the chassis, and the bezel is connected to the front of the chassis to position low-impedance vents in the bezel across the air inlet and proximal to the inlet face of the honeycomb fin structure. The honeycomb fin structure dissipates heat from an electronic component that is disposed within the chassis and is in thermal communication with the fin structure. The size of the air channels in the fin structure are sized to provide EMR shielding that blocks EMR from traversing the air inlet of the chassis. The dual purpose served by the strategic positioning of the fin structure eliminates the need for more restrictive, EMR-shielding vents in the bezel. Eliminating the restrictive vents decreases air flow impedance into the chassis. In addition, the EMR containment is improved due to the extended depth of the air channels of the (honeycomb) heat sink (e.g., the depth being from the inlet face to the outlet face) as compared to the relatively shorter depth of, for example, hex perforations in a conventional bezel, which are usually formed of thin sheet metal.

In another embodiment of the system of the present invention, a heat-generating electronic device is disposed on a circuit board at a forward position near a front of the chassis adjacent to low-impedance vents in a bezel to minimize preheating of air entering the chassis through the vents. A heat sink comprising a base and a fin structure with an inlet face, and outlet face and a plurality of interconnected air channels disposed therebetween is positioned in thermal contact or communication with the component. The inlet face of the fin structure is disposed proximal the vents of the bezel to provide an obstacle to EMR traversing the air inlet opening in the chassis. In this manner, the fin structure can be used to replace, for example, restricted-flow hex perforations in the bezel. By projecting the inlet face of a fin structure to the front of the Faraday cage, the air flow impedance of the vents in the bezel can be decreased due to the high free air ratio of the fin structure and due to the elimination of the mismatch in the “line of sight” between the vents in the bezel and the fin structure.

In addition to improved cooling air flow and improved EMR containment, an additional benefit of the present invention is the reduced cost of making the bezel. Larger vents are easier to make by, for example, drilling or punching, and where such vents are made by drilling or punching, the sheet metal from which the bezel is made can be thinner for making larger vents without causing an extruded or cone-shaped portion around each aperture or vent. Another advantage available through the use of fin structures comprising a plurality of air channels is that a single fin structure can be used to dissipate heat from multiple heat-generating components because, in some embodiments, the fin structure may exhibit elasticity or compliance to facilitate alignment and engagement with components that may not be line-of-sight aligned one with others. Compliance in the fin structure allows the fin structure to be deformed slightly to facilitate contacting components that may not be aligned or have the same height above the circuit board. Also, a single fin structure with interconnect air channels can be thermally coupled to multiple bases on multiple heat-generating electronic components using strategically placed and strategically shaped heat spreaders and/or heat pipes. A hot end of a heat spreader or heat pipe can be connected to a base disposed on a component and a cool end of the heat spreader or heat pipe can be connected to the fin structure. A favorable connection between the heat spreader and/or heat pipe and the fin structure can be obtained using a spring assembly to provide residual pressure urging the heat spreader or heat pipe against the base or the fin structure. Additional increases in efficiency may result from the use of heat spreaders and/or heat pipes to distribute heat about the periphery of the fin structure for more uniform heat dissipation by the air channels therein.

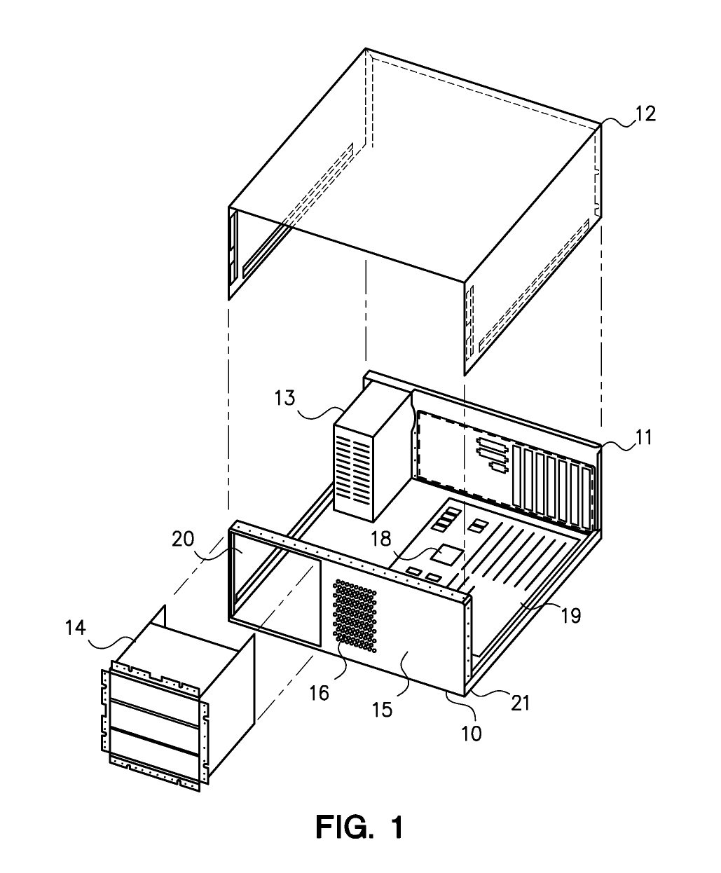

FIG. 1 is an exploded perspective view of a conventional electromagnetic radiation (EMR) containment system comprising a metal chassis 10 having a bottom portion 11, a generally U-shaped top portion 12 and a bezel 15 with restricted vents 16 connectable to a front 21 of the bezel 15 to block EMR from traversing the bezel 15. The bezel 15 further comprises a port 20 to receive an input/output device 14 therein. The bottom portion 11 of the chassis 10 receives a circuit board 19 having a processor 18 connected thereon and a power module 13 to house devices to receive and manage an electrical power supply, such as an electrical relay (not shown). It should be noted that the large number of conventional vents 16 in the bezel 15 are very small in size, thereby giving rise to a substantial restriction in air flow into the chassis 10.

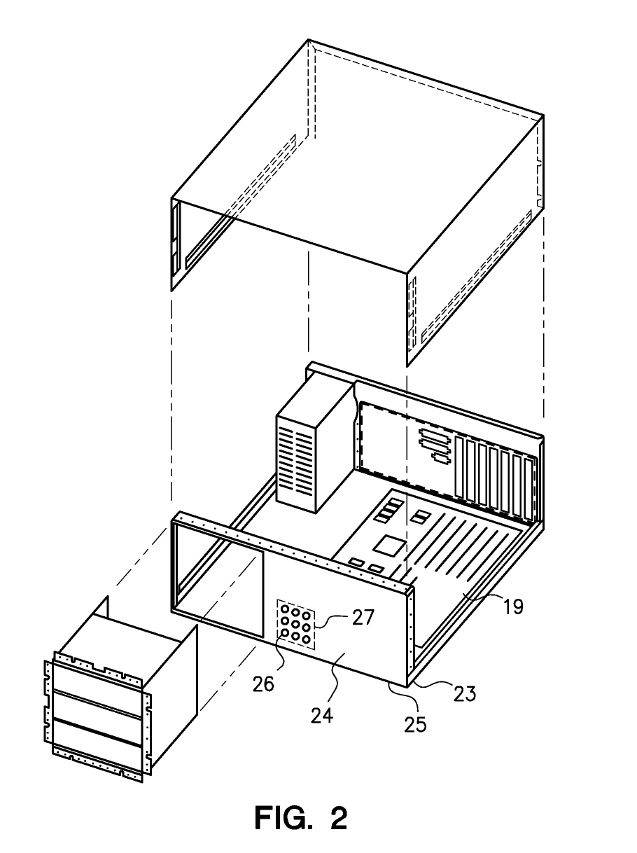

FIG. 2 is a perspective view of an embodiment of an EMR containment system of the present invention having chassis 23, a heat sink (not shown—hidden by bezel 24) coupled in a forward position within the chassis 23, and a bezel 24 connected to a front 25 of the chassis 23 to position low-air-flow-impedance vents 26 within the bezel 24 proximal an inlet face (not shown) of the fin structure (not shown) to impede EMR from traversing the bezel 24. The vents 26 in the bezel 24 of FIG. 2 are disposed within a vent portion 27 of the bezel 24 indicated by the dotted line surrounding the low-impedance vents 26. A circuit board 19 is disposed within the chassis 23 to connect to a heat-generating electronic device (not specifically identified).

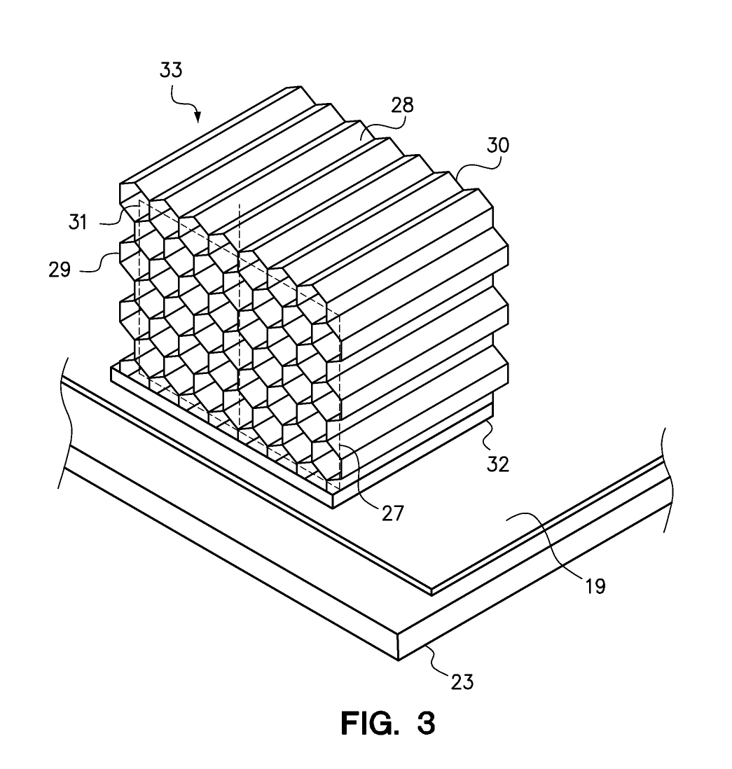

FIG. 3 is an enlarged perspective view of a portion of the EMR containment system of FIG. 2 with the bezel 24 removed to reveal a heat sink 33 having a base 32 and a fin structure 28 comprising an inlet face 29, and outlet face 30 and a plurality of interconnected air channels 31 extending therebetween. The base 32 of the heat sink 33 is releasably connected to a processor (not shown) on the circuit board 19. The air channels 31 of the heat sink 33 in FIG. 3 are generally hexagonal in cross-section, but may in other embodiments of the present invention be circular, triangular, polygonal, trapezoidal, pentagonal or some other shape in cross-section, and the structure of the air channels 31 of a fin structure 28 is limited only by the claims that follow. The vent portion 27 of the bezel 24 of FIG. 2 is shown superimposed on the inlet face 29 of the fin structure 28 in FIG. 3 to indicate the proximal position of the inlet face 29 of the fin structure 28 of the heat sink 33 relative to the low-impedance vents (not shown) of the bezel when the bezel is attached to the chassis for EMR containment.

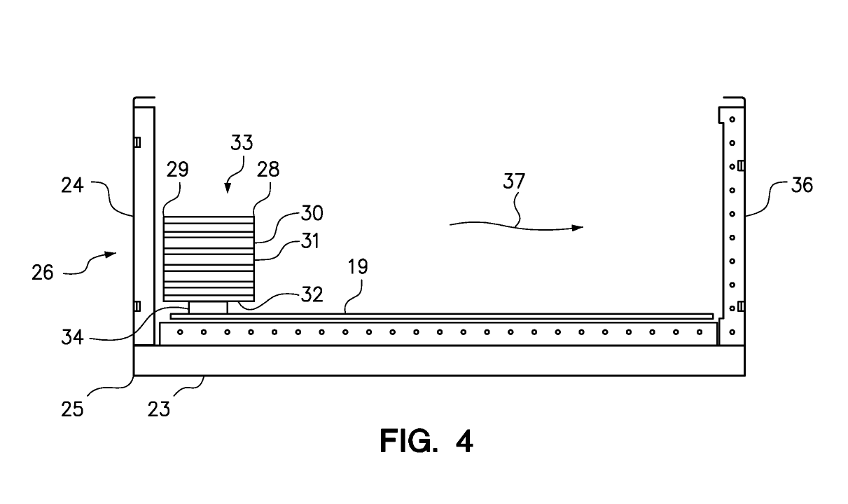

FIG. 4 is a side elevation view of the EMR containment system of FIGS. 2 and 3 comprising the chassis 23, the circuit board 19, the bezel 24 connected to the front 25 of the chassis 23, and the heat sink 33. FIG. 4 illustrates the proximity of the inlet face 29 of the fin structure 28 of the heat sink 33 relative to the air inlet to the chassis, which is spanned by the low-impedance vents 26 of the bezel 24. The fin structure 28 is connected to the base 32 of the heat sink 33 which is connected to a processor 34 on the circuit board 19. It will be understood that an air mover (not shown), such as a fan, disposed either at a rear 36 of the chassis 23 or external to the chassis 23 moves air through the vents 26 in the bezel 24, through the air channels 31 of the fin structure 28 the heat sink 33 and through the chassis 23 in the direction of the arrow 37 (left to right as illustrated in FIG. 4). It will be further understood that the temperature of the air exiting the air channels 31 of the heat sink 33 at the outlet face 30 is warmer than the air entering the air channels 31 at the inlet face 29.

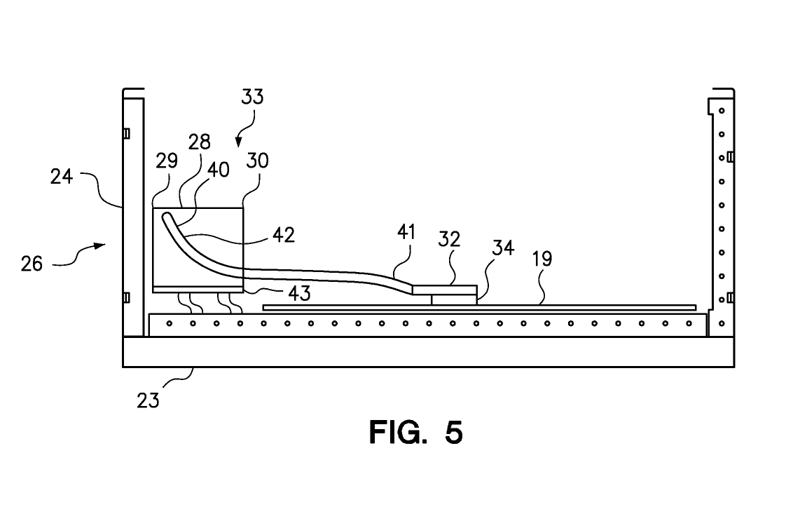

FIG. 5 is a side elevation view of an alternate embodiment of the EMR containment system of the present invention having a bezel 24 with low-impedance vents 26 disposed proximal the inlet face 29 of a fin structure 28 that is thermally coupled to a base 32 on a heat-generating electronic component 34 located on a circuit board 19 at a position that is distal to the bezel 24. The fin structure 28 is thermally coupled to the base 32 through a heat bus 40 such as a heat spreader or a heat pipe. The heat bus 40 comprises a hot end 41 connected to the base 32 and a cold end 42 connected to the fin structure 28. The fin structure 28 may additionally comprise a platform 43 to support the fin structure 28 relative to the chassis 23 or to couple the fin structure 28 directly to the chassis 23, such as attaching the fin structure to the front wall or bezel of the chassis.

A “heat bus,” as that term is used herein, is a heat conduit to transfer heat from a hot end 41 at the base 32 to at least one cold end 42 at a fin structure remote from the base 32. The heat bus 40 may comprise a spreader bar, which may be an elongate and/or branched heat conduit having a generally solid core to conduct heat from a hot end to at least one cold end, and the spreader bar may comprise a highly thermally conductive material such as copper. Alternately, the heat bus 40 may comprises a heat pipe having a hollow core (not shown) containing a volatile material that moves heat from the hot end 41 to the cold end 42 of the heat pipe by use of the evaporation—condensation cycle. Heat conducted from the component 34 to the base 32 boils liquid material within the core (not shown) at the hot end 41 of the heat bus 40. The vaporous material moves, either by wick or by gravity separation, or both, from the hot end 41 (or from near the hot end 41) to the cold end 42 (or to near the cold end 42) where the vapor cools and condenses back into the liquid phase.

Optionally, a heat bus 40 may comprise two or more legs or branches at the hot end 41 to enhance heat gathering or it may comprise two or more legs or branches at the cold end 42 to enhance heat distribution to the fin structure 28. A heat bus may be adapted to advantageously distribute heat about the periphery of a fin structure 28.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A system, comprising:
a chassis having an air inlet and an air outlet;
a circuit board with a heat-generating electronic component within the chassis; and
a heat sink having a base to engage the heat-generating electronic component and a fin structure with an inlet face, an outlet face and a plurality of interconnected air channels therebetween, wherein the fin structure is electrically grounded and spans the air inlet, and wherein the air channels of the fin structure are sized to block electromagnetic radiation (EMR) from traversing the air inlet.

2. The system of claim 1, wherein the base of the heat sink comprises a heat spreader to transfer heat from the base to the fin structure.

3. The system of claim 1, wherein the base of the heat sink comprises a heat pipe to transfer heat from the base to the fin structure.

4. The system of claim 1, wherein the base comprises a second face to support the fin structure.

5. The system of claim 1, wherein the heat-generating electronic component is a processor.

6. The system of claim 1, wherein a plurality of the air channels of the fin structure have at least one of a hexagonal, pentagonal, polygonal, trapezoidal, triangular and circular cross-section.

7. The system of claim 1, further comprising:
a bezel with low-impedance vents connectable to the chassis to span across the air inlet to the chassis.

8. The system of claim 7, wherein the low-impedance vents are aligned with the air channels of the fin structure.

9. The system of claim 7, wherein the clearance between the vents of the bezel and the inlet of the fin structure is less than 25 mm.

10. The system of claim 7, wherein the clearance between the vents of the bezel and the inlet of the fin structure is less than 15 mm.

11. The system of claim 7, wherein the clearance between the vents of the bezel and the inlet of the fin structure is less than 5 mm.

12. The system of claim 1, wherein the circuit board has a second heat-generating electronic component within the chassis, and wherein the fin structure extends into thermal communication with both heat-generating electronic components.

13. A system, comprising:
a chassis having an air inlet and an air outlet;
a circuit board with a heat-generating electronic component within the chassis; and
a heat sink having a base to engage the heat-generating electronic component and a fin structure with an inlet face, an outlet face and a plurality of interconnected air channels therebetween, wherein the fin structure is electrically grounded and spans the air inlet, wherein the chassis and the fin structure form a Faraday cage.

14. A method to contain electromagnetic radiation within a computer chassis comprising:
disposing a heat-generating electronic component on a circuit board within a chassis having an air inlet;
engaging the heat-generating electronic component with a base of a heat sink, wherein the base is thermally coupled to a fin structure having an inlet face, an outlet face and interconnected air channels therebetween;
positioning the inlet face of the fin structure forward within the chassis and proximal the air inlet to the chassis; and
electrically grounding the fin structure, wherein the air channels of the fin structure are sized to block EMR from traversing the air inlet to the chassis.

15. The method of claim 14, further comprising:
attaching a releasably attachable bezel across the air inlet to the chassis, wherein the bezel have low-impedance vents therethrough.

16. The method of claim 15, wherein the low-impedance vents perform substantially no EMR blocking.

17. The method of claim 14, further comprising:
thermally coupling the base of the heat sink to the fin structure using a heat spreader or a heat pipe.

18. The method of claim 15, wherein positioning the inlet face of the fin structure proximal the air inlet to the chassis comprises positioning the inlet face of the fin structure within 15 mm of the vents of the bezel.

19. The method of claim 15, wherein positioning the inlet face of the fin structure proximal the air inlet to the chassis comprises positioning the inlet face of the fin structure within 5 mm of the vents of the bezel.
